(19) United States
(12) Patent Application Publication
(10) Pub. No.: US 2018/0041187 A1
(43) Pub. Date: Feb. 8, 2018

(54) SURFACE ACOUSTIC WAVE ELEMENTS HAVING IMPROVED RESISTANCE TO CRACKING, AND METHODS OF MANUFACTURING SAME

(71) Applicant: SKYWORKS FILTER SOLUTIONS JAPAN CO., LTD., Kadoma-Shi (JP)

(72) Inventors: Yuji Yashiro, Kizugawa-Shi (JP); Hideki Yamabe, Osaka-Fu (JP); Hidehito Shimizu, Neyagawa-Shi (JP); Satoru Matsuda, Toyonaka-Shi (JP); Atsushi Nishimura, Nishinomiya-Shi (JP); Hironori Fukuhara, Osaka-Fu (JP); Toru Yamaji, Nagaokakyou-Shi (JP)

(21) Appl. No.: 15/665,740

(22) Filed: Aug. 1, 2017

Related U.S. Application Data
(60) Provisional application No. 62/512,813, filed on May 31, 2017.
(60) Provisional application No. 62/370,773, filed on Aug. 4, 2016.

(51) Int. Cl. H03H 9/02

(52) U.S. Cl. CPC H03H 9/02984; H03H 9/02897; H03H 9/02929; H03H 9/02574

(57) ABSTRACT

Examples are directed to suppressing crack development in a surface acoustic wave (SAW) element including a double-layered IDT electrode. In one example the SAW element includes a piezoelectric substrate, a comb-shaped electrode formed on a top surface of the piezoelectric substrate, and an insulation layer formed on the top surface of the piezoelectric substrate to cover the comb-shaped electrode. The comb-shaped electrode includes a plurality of electrode fingers each having a first metal layer of a first metal formed on the top surface of the piezoelectric substrate, a second metal layer of a second metal formed on the first metal layer, and a second protective film at least partially covering the second metal layer, the second metal layer being covered by the second protective film and the first metal layer.

### CROSS-REFERENCE TO RELATED APPLICATIONS

This application claims the benefit under 35 U.S.C. §119(e) of co-pending U.S. Provisional Application No. 62/370,773 titled “SURFACE ACOUSTIC WAVE ELEMENTS AND METHODS OF MANUFACTURING SAME” and filed on Aug. 4, 2016, and of co-pending U.S. Provisional Application No. 62/512,813 titled “SURFACE ACOUSTIC WAVE ELEMENTS HAVING IMPROVED RESISTANCE TO CRACKING, AND METHODS OF MANUFACTURING SAME” filed on May 31, 2017, both of which are incorporated herein by reference in their entireties for all purposes.

### BACKGROUND

Conventionally, an interdigital transducer (IDT) electrode forming a surface acoustic wave (SAW) resonator in a SAW element is configured as a double-layered structure that combines one layer made of a heavier metal such as molybdenum with another other layer made of a more conductive metal such as aluminum in order to provide both appropriate weight and conductivity to the electrode fingers. Further, certain devices include a protective film on the surface of such a double-layered IDT electrode to prevent issues such as void formation, fracturing, spurious emission and the like. Japanese Patent Application Publication No. 2006-109287, Japanese Patent Application Publication No. 2007-282294, and International Application No. WO2012/090698 disclose examples of such devices.

FIG. 1 is a cross-sectional view showing the structure of a conventional double-layered IDT electrode 110. The IDT electrode 110 includes a first metal layer 111 made of molybdenum formed on a top surface of a piezoelectric substrate 120 and a second metal layer 112 made of aluminum formed on the first metal layer 111 and having a trapezoidal cross-section. An insulation layer 130 made of silicon dioxide (SiO₂) is formed over the top surface of the piezoelectric substrate 120 to cover the IDT electrode 110.

### SUMMARY OF INVENTION

Aspects and embodiments relate to a surface acoustic wave (SAW) element using a piezoelectric substrate and a method of manufacturing the same.

In the conventional IDT electrode 110 as shown in FIG. 1, tensile stress (represented by arrows 142) concentrates in regions 152 of the IDT electrode 110 where the second metal layer 112 has a cross-sectional shape with an acute angle, around a point where an interface between the first metal layer 111 of molybdenum and the second metal layer 112 of aluminum is in contact with the insulation layer 130 of silicon dioxide. Because this tensile stress can be repeatedly applied in a higher temperature environment in which the SAW element operates, a crack may develop in a cracking direction 162 from the acute-angled region 152 into the insulation layer 130. Consequently, the insulation layer 130 may be fractured and the SAW element may be broken. Even using the technique of providing a protective layer over the double-layered electrode as disclosed in the above-mentioned applications, it has not been possible to sufficiently suppress the crack development along the cracking direction 162.

Aspects and embodiments are directed to addressing the above-mentioned problem, and provide a SAW element having a multi-layered, for example double-layered, IDT electrode in which crack development can be sufficiently suppressed to prevent fractures, and a method of manufacturing the same.

According to certain embodiments, a surface acoustic wave device comprises a piezoelectric substrate, a comb-shaped electrode formed on a top surface of the piezoelectric substrate and including a plurality of electrode fingers, each electrode finger including a first metal layer made of a first metal and formed on the top surface of the piezoelectric substrate, a second metal layer made of a second metal and formed on the first metal layer, and a first protective film at least partially covering the second metal layer, and an insulation layer formed over the top surface of the comb-shaped electrode to cover the piezoelectric substrate.

In one example the first metal has a first conductivity and the second metal has a second conductivity greater than the first conductivity. In another example the first metal has a first density and the second metal has a second density less than the first density. In one example the first metal layer is made of molybdenum and the second metal layer is made of aluminum. In one example the first protective film is made of aluminum oxide.

In one example the second metal layer has a trapezoidal cross-section taken along a line perpendicular to an extending direction of the electrode finger. In one example the first protective film covers side surfaces and a top surface of the second metal layer. In another example the first protective film covers side surfaces of the second metal layer and does not extend over a top surface of the second metal layer.

In one example the insulation layer is made of a first material having a first fracture toughness value, and the first protective film is made of a second material having a second fracture toughness value greater than the first fracture toughness value. In one example the second material of the first protective film is oxidized from the second metal. In another example the second material of the first protective film is nitrided from the second metal.

In one example each electrode finger further includes a third metal layer made of the first metal and disposed on a top surface of the second metal layer. The second metal layer may be covered by the first protective film, the first metal layer, and the third metal layer. In another example each electrode finger further includes a fourth metal layer made of the second metal and disposed on a top surface of the third metal layer. In one example the fourth metal layer has a trapezoidal cross-section taken along a line perpendicular to an extending direction of the electrode finger. Each electrode finger may further include a second protective film covering side surfaces and a top surface of the fourth metal layer.

In one example each electrode finger further includes a second protective film at least partially covering the first metal layer, the first metal being covered by the second protective film and the top surface of the piezoelectric substrate. The second protective film may include material oxidized from the first metal.

According to certain embodiments a method of manufacturing a surface acoustic wave device comprises forming a comb-shaped electrode on a top surface of a piezoelectric substrate, and forming an insulation layer on the top surface of the piezoelectric substrate to cover the comb-shaped electrode. Forming the comb-shaped electrode may include forming a first metal layer made of first metal on the top surface of the piezoelectric substrate, forming a second metal layer made of second metal on the first metal layer, and oxidizing a surface of the second metal layer to form a protective film on the second metal layer, the second metal layer being covered by the protective film and the first metal layer.

In one example of the method forming the second metal layer includes forming the second metal layer to have a trapezoidal cross-section taken along a line perpendicular to an extending direction of an electrode finger of the comb-shaped electrode.

According to certain aspects and embodiments, crack development is suppressed or prevented from occurring in a SAW element including a multi-layered, for example double-layered, IDT electrode, such that the SAW element is prevented from fracturing.

Still other aspects, embodiments, and advantages of these exemplary aspects and embodiments, are discussed in detail below. Any embodiment disclosed herein may be combined with any other embodiment in any manner consistent with at least one of the objects, aims, and needs disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described in connection with the embodiment may be included in at least one embodiment. The appearances of such terms herein are not necessarily all referring to the same embodiment. The accompanying drawings are included to provide illustration and a further understanding of the various aspects and embodiments, and are incorporated in and constitute a part of this specification. The drawings, together with the remainder of the specification, serve to explain principles and operations of the described and claimed aspects and embodiments.

### BRIEF DESCRIPTION OF THE DRAWINGS

Various aspects of at least one embodiment are discussed below with reference to the accompanying figures, which are not intended to be drawn to scale. In the figures, each identical or nearly identical component that is illustrated in various figures is represented by a like numeral. For purposes of clarity, not every component may be labeled in every figure. The figures are provided for the purposes of illustration and explanation and are not intended as a definition of the limits of the invention. In the figures:

FIG. 1 is a cross-sectional view showing the structure of a conventional electrode;

FIG. 2 is a cross-sectional view showing one example of an arrangement of electrodes according to aspects of the present invention;

FIG. 3 is a cross-sectional view showing a structure of an electrode corresponding to the example shown in FIG. 2;

FIG. 4A is a cross-sectional view showing stress distribution in an electrode according to the example of FIG. 2;

FIG. 4B is a cross-sectional view showing stress distribution in a comparative example of an electrode;

FIG. 5 is a graph showing a relationship between a lifetime and a frequency of an electrode according to the example of FIG. 2;

FIGS. 6A, 6B, and 6C are cross-sectional views showing structures of electrodes corresponding to lines A, B and C, respectively, indicated in FIG. 5;

FIG. 7 is a graph showing a relationship between a thickness of the protective film and a lifetime of the electrode according to the example of FIG. 2;

FIGS. 8A to 8D are cross-sectional views showing electrode structures corresponding to a series of method steps of manufacturing an electrode according to the example of FIG. 2;

FIG. 9 is a cross-sectional view showing the structure of another example of an electrode according to aspects of the present invention;

FIG. 10 is a graph showing a relationship between a thickness of the protective film and a lifetime of the electrode according to the example of FIG. 9;

FIG. 11 is a cross-sectional view showing the structure of another example of an electrode according to aspects of the present invention;

FIG. 12 is a cross-sectional view showing the structure of another example of an electrode according to aspects of the present invention;

FIG. 13 is a cross-sectional view showing the structure of another example of an electrode according to aspects of the present invention;

FIG. 14 is a cross-sectional view showing the structure of another example of an electrode according to aspects of the present invention;

FIG. 15 is a cross-sectional view showing the structure of another example of an electrode according to aspects of the present invention;

FIG. 16 is a cross-sectional view showing the structure of another example of an electrode according to aspects of the present invention;

FIG. 17 is a block diagram of one example of a filter module including a surface acoustic wave device having an electrode structure according to aspects of the present invention; and

FIG. 18 is a block diagram of an example of a wireless device including the filter module of FIG. 17 according to aspects of the present invention.

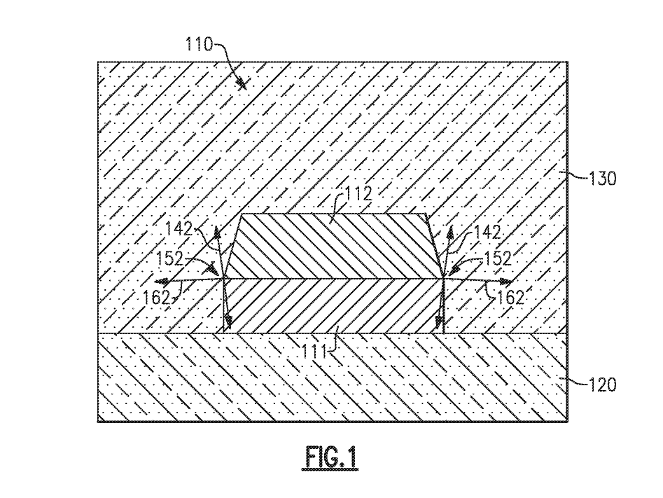

### DETAILED DESCRIPTION

Embodiments of surface acoustic wave (SAW) elements and methods of manufacturing the same are described below in detail with reference to the drawings.

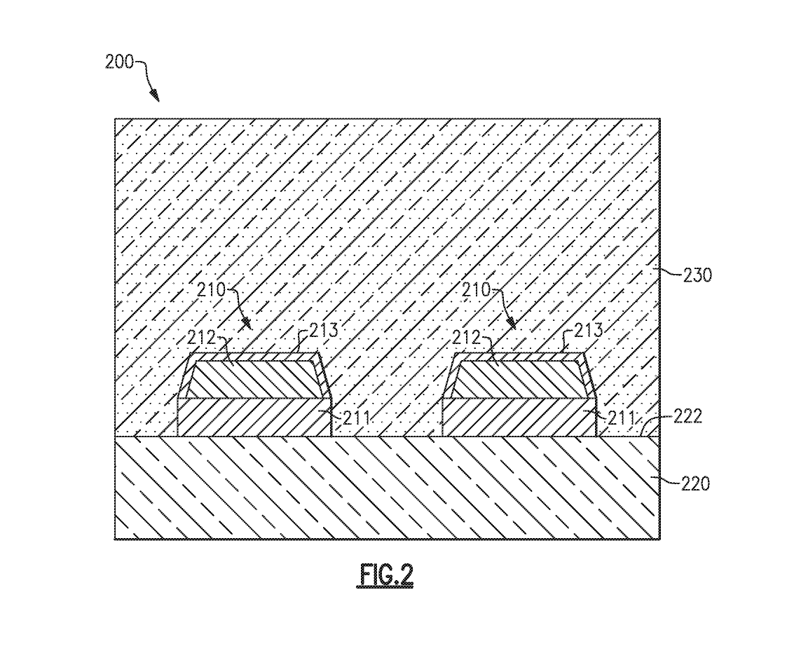

FIG. 2 is a cross-sectional view of a SAW resonator comb-shaped IDT electrode included in a SAW element 200 according to a first embodiment, the cross-section being taken along a line perpendicular to an extending direction of electrode fingers of the IDT electrode. FIG. 2 shows two electrodes 210 representing a plurality of electrode fingers of the IDT electrode. Each of the electrodes 210 has a certain width. The electrodes 210 are disposed on a top surface 222 of a piezoelectric substrate 220 with a certain pitch relative to each other.

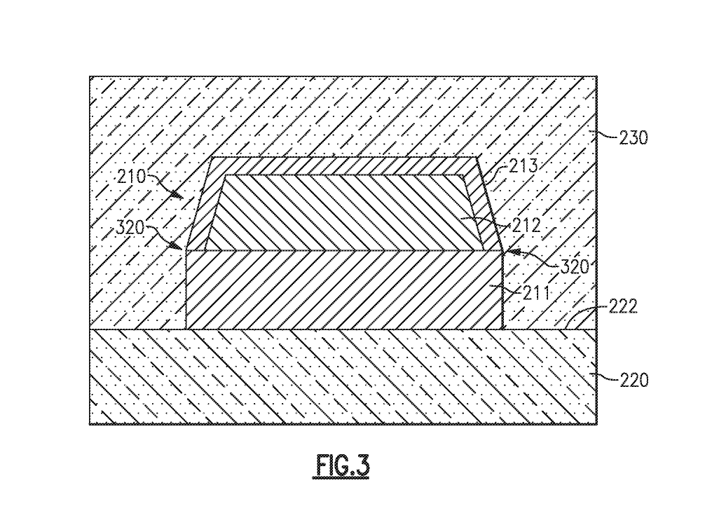

FIG. 3 is an enlarged cross-sectional view showing an example of the structure of one of the electrodes 210. For simplicity, FIG. 3 shows a cross-section of a single electrode 210 representing one of the electrode fingers of the IDT electrode included in the SAW element 200 to illustrate the structure of the electrode 210. Similarly in the following cross-sectional views, a cross-section of a single electrode 210 is shown representing the IDT electrode.

Referring to FIGS. 2 and 3, according to the first embodiment, the electrode 210 forming the IDT electrode of the SAW resonator is formed on a flat top surface 222 of the piezoelectric substrate 220, which is made of piezoelectric material (also called a piezoelectric body) such as lithium niobate (LiNbO₃), for example. An insulation layer 230 made of silicon dioxide (SiO₂) is formed on the piezoelectric substrate 220, covering the electrode 210.

In the electrode 210, a first metal layer 211 made of molybdenum is formed on the top surface 222 of the piezoelectric substrate 220, the first metal layer 211 having a certain width and height. A second metal layer 212 made of aluminum is formed on the first metal layer 211. The second metal layer 212 has a trapezoidal cross-section, such that its width becomes less as its height becomes more elevated from the top surface 222 of the piezoelectric substrate 220.

The density of molybdenum included in the first metal layer 211 is greater than the density of aluminum included in the second metal layer 212, and therefore the first metal layer 211 of molybdenum can bear weight for providing an adequate mass for the electrode 210. In other words, the density of the second metal layer 212 is less than that of the first metal layer 211. The conductivity of aluminum included in the second metal layer 212 is greater than the conductivity of the first metal layer 211, and therefore the second metal layer 212 of aluminum provides adequate conductivity for the electrode 210.

The second metal layer 212 has side and top surfaces, the aluminum of which is converted into aluminum oxide (Al₂O₃) to a certain depth to form a protective film 213. A side surface of the first metal layer 211 of molybdenum is smoothly connected at the upper edge thereof to a corresponding side surface of the protective film 213 of aluminum oxide at the lower edge thereof. The first metal layer 211 of molybdenum or the protective film 213 of aluminum oxide is disposed between the second metal layer 212 of aluminum and the insulation layer 230 of silicon dioxide, such that the aluminum of the second metal layer 212 can be covered and protected by the molybdenum of the first metal layer 211 and/or by the aluminum oxide of the protective film 213.

As listed in TABLE 1 below, each of molybdenum (Mo) and aluminum oxide (Al₂O₃) has a coefficient of thermal expansion (such as linear expansion coefficient) lower than that of aluminum (Al). Further, each of molybdenum and aluminum oxide has a Young's modulus greater than that of aluminum. Accordingly, the first metal layer 211 of molybdenum and the protective film 213 of aluminum oxide that cover the second metal layer 212 may mitigate thermal expansion of the second metal layer 212 of aluminum to suppress any effect thereof on the insulation layer 230 of silicon dioxide.

TABLE 1

| | Linear expansion coefficient | |
|---|---|---|
| Material | [10⁻⁶/° C.] | Young's modulus |
| Al | 23 | 70 |
| Al₂O₃ | 7 | ~400 |
| Mo | 5 | 324 |

Further, as listed in TABLE 2, each of molybdenum (Mo) and aluminum oxide (Al₂O₃) has a fracture toughness greater than that of silicon dioxide (SiO₂). Accordingly, the first metal layer 211 of molybdenum and the protective film 213 of aluminum oxide may not be fractured prior to the fracturing of the insulation layer 230 of silicon dioxide. Therefore, due to the presence and arrangement of the first metal layer 211 of molybdenum and/or the protective film 213 of aluminum oxide, cracking can be prevented from developing into the insulation layer 230 of silicon dioxide.

TABLE 2

| Material | Fracture toughness value Kc |
|---|---|
| SiO₂ | 1.5 |
| AlN | 3 |
| Al₂O₃ | 4 |
| Si₃N₄ | 7 |
| Mo | 50 |

As listed in TABLE 2, each of aluminum nitride (AlN) and silicon nitride (Si₃N₄) has fracture toughness greater than that of silicon dioxide. Accordingly, even if the protective film 213 is made of aluminum nitride or silicon nitride instead of aluminum oxide, the protective film 213 may not be fractured prior to the fracturing of the insulation layer 230 of silicon dioxide. Therefore, due to presence and arrangement of the first metal layer 211 of molybdenum and/or the protective film 213 of aluminum nitride or silicon nitride, cracking can be prevented from developing into the insulation layer 230 of silicon dioxide.

Further, the protective film 213 of aluminum oxide has higher fracture toughness by itself. Accordingly, even if cracking occurs in the protective film 213 along an interface between the second metal layer 212 of aluminum and the protective film 213 of aluminum oxide, the crack development into the insulation layer 230 can be suppressed.

Each of aluminum nitride and silicon nitride also has higher fracture toughness by itself. Accordingly, when the protective film 213 is made of aluminum nitride or silicon nitride instead of aluminum oxide, crack development can be suppressed even if cracking occurs in the protective film 213 along an interface between the second metal layer 212 of aluminum and the protective film 213 of aluminum nitride or silicon nitride.

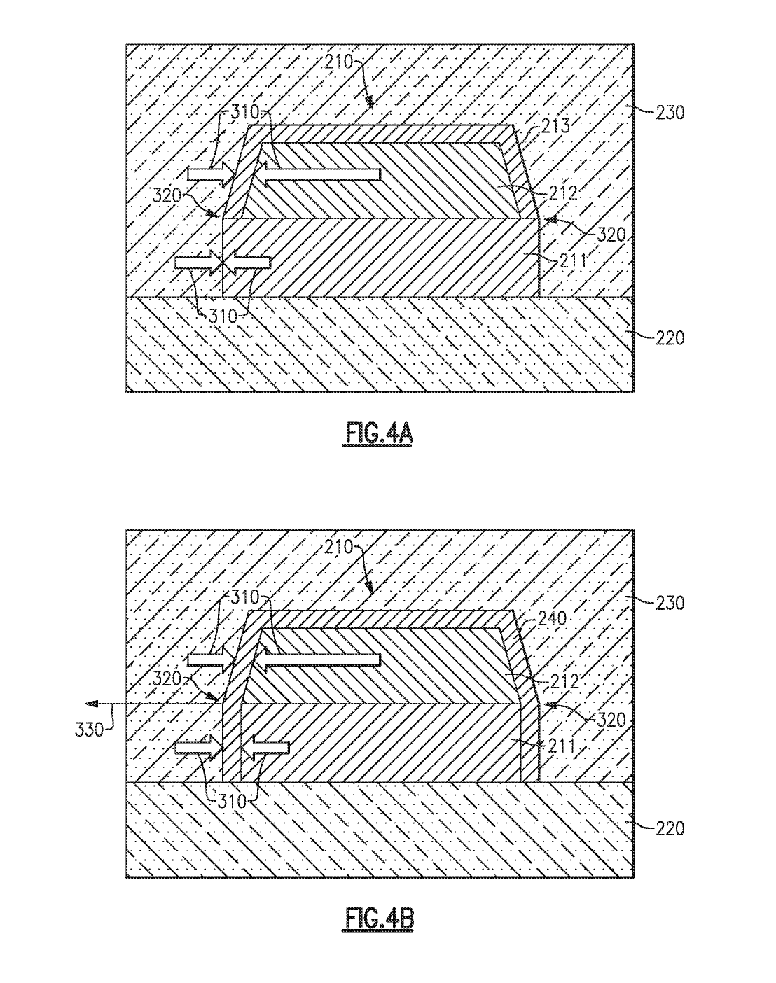

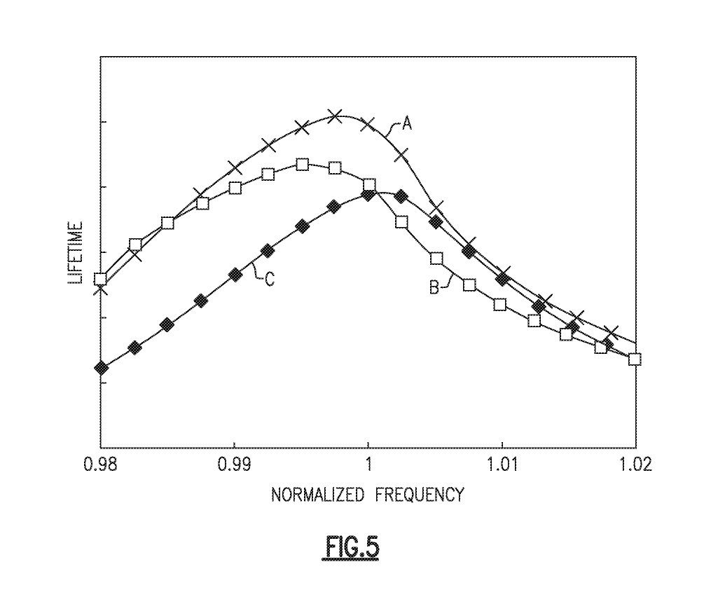

FIGS. 4A and 4B show how stresses (represented by arrows 310) act on the insulation layer 230 of silicon dioxide. FIG. 4A shows the electrode 210 of the first embodiment. According to the first embodiment, the protective film 213 of aluminum oxide is formed on side and top surfaces of the second metal layer 212 of aluminum, as discussed above. Therefore, the stresses 310 are unlikely to be concentrated within the protective film 213.

FIG. 4B shows another structure as a comparative example in which a protective film 240 of aluminum oxide having a certain film thickness is formed covering the side and top surfaces of the electrode 210. In the comparative example, like reference numerals refer to like components corresponding to first embodiment. The difference in expansion coefficient between the first metal layer 211 of molybdenum and the second metal layer 212 of aluminum may allow the stresses 310 to be concentrated in the protective film 240 at a portion in contact with an acute-angled region 320 of the second metal layer 212, such that cracking may tend to occur in a direction 330 from the interface with the insulation layer 230.

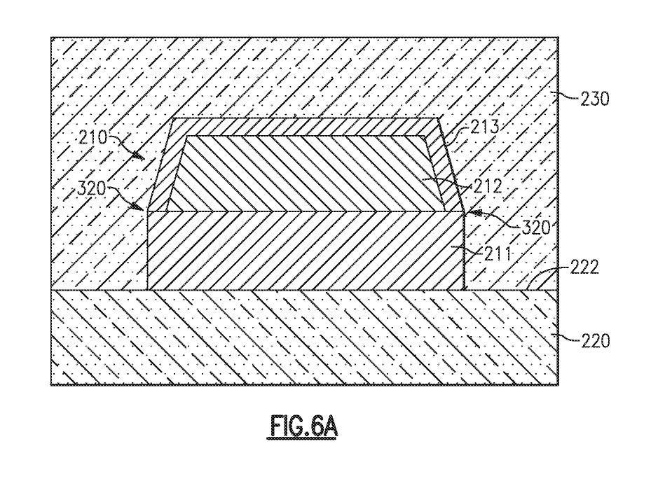

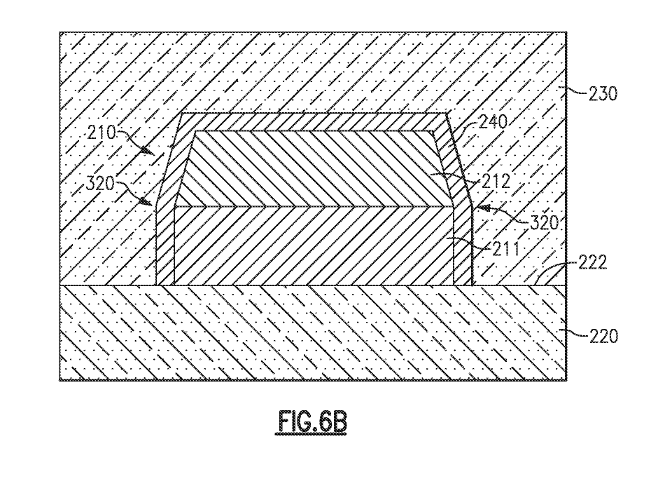

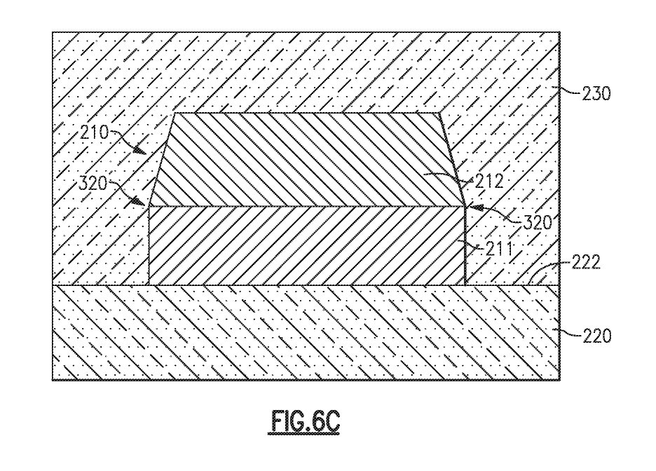

FIG. 5 is a graph showing a relationship between a lifetime of a SAW element and an electrode structure of the SAW element, as a function of frequency. In FIG. 5, the horizontal axis represents normalized frequency relative to the resonance frequency of the SAW element, and the vertical axis represents the device lifetime in arbitrary units. FIGS. 6A-6C illustrate cross-sectional views showing structures of the electrodes corresponding to lines A, B and C, respectively, as shown in the graph of FIG. 5. FIG. 6A corresponds to line A, and shows the structure of electrode 210 according to the first embodiment similar to that of FIG. 3. FIG. 6B corresponds to line B, and shows the structure of the electrode 210 as a comparative example, similar to that of FIG. 4B, in which the side and top surfaces of the electrode 210 are entirely covered with the protective film 240 of aluminum oxide having a certain thickness. FIG. 6C corresponds to line C, and shows the structure of the electrode 210 as another comparative example in which none of the side and top surfaces are covered with a protective film. In FIGS. 6B and 6C, like numerals refer to like components corresponding to the first embodiment of FIG. 6A.

The lifetime of the SAW element shown in FIG. 5 was measured as follows: a power of 1 W was applied across the SAW element maintaining the temperature at 100° C. and then the time was measured until the insulation layer 230 was fractured. The film thicknesses of the protective film 213 and the protective film 240 were each 20 nm. The lifetime decreased in each of the comparative examples (lines B and C) at the resonance frequency or greater as compared to the SAW element of the first embodiment (line A).

Referring to FIGS. 4A and 4B showing the distribution of stresses 310, and to FIG. 5, it can be seen that the structure according to the first embodiment of FIG. 6A suppressed cracking and extended the lifetime of the SAW element over the entire frequency range. Further, the structure of FIG. 6B, corresponding to FIG. 4B and having the protective film 240 formed over the entire surfaces of the electrode 210, allowed the stresses to be concentrated on the interface with the acute-angled region 320 and cracking occurred such that the lifetime was shorter at the resonance frequency or greater as compared to the lifetime of the SAW device of FIG. 6C having no protective film.

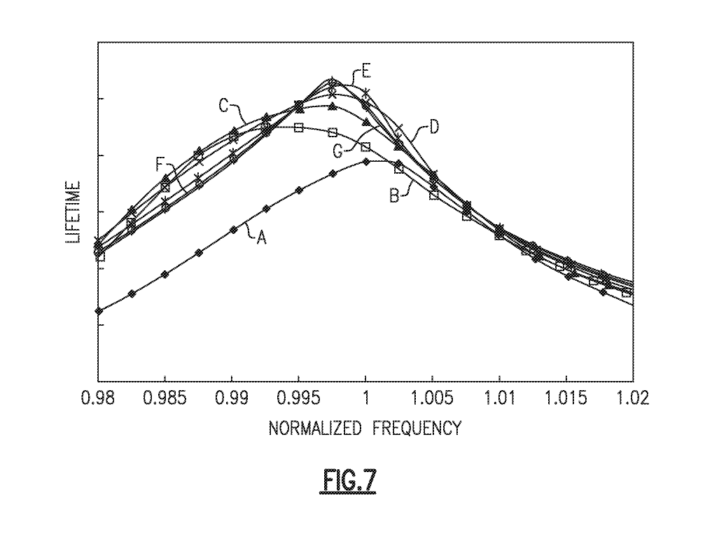

FIG. 7 is a graph showing a relationship between the lifetime of the SAW element and a film thickness of the protective film 213 according to the first embodiment. In FIG. 7, the horizontal axis represents normalized frequency relative to the resonance frequency of the SAW element, and the vertical axis represents the lifetime of the device in arbitrary units. In FIG. 7, line A (♦) corresponds to the SAW element having no protective film 213, and lines B (□), C (▴), D (x), E (*), F (∘) and G (|) correspond to film thicknesses of 5 nm, 10 nm, 20 nm, 50 nm, 80 nm and 100 nm, respectively, for the protective film 213.

The lifetime of the SAW element shown in FIG. 7 was measured as follows: a power of 1 W was applied across the SAW element maintaining the temperature at 100° C. and then the time was measured until the insulation layer 230 was fractured, similar to the case of FIG. 5. The results presented in FIG. 7 show that the protective film 213 having film thickness of 5 nm (line B) indicates a longer lifetime at the resonance frequency or higher frequencies as compared to the lifetime of a device having no protective film (line A). As shown by lines C to G, the protective film 213 having a film thickness of 10 nm or greater may extend the lifetime of the device at the resonance frequency or higher frequencies as compared to either the case with no protective film (corresponding to line A) or the case where the protective film 213 has a film thickness of 5 nm (corresponding to line B). However, a convergence of lines E to G can be seen corresponding to the protective film 213 having a film thickness of 50 nm or greater.

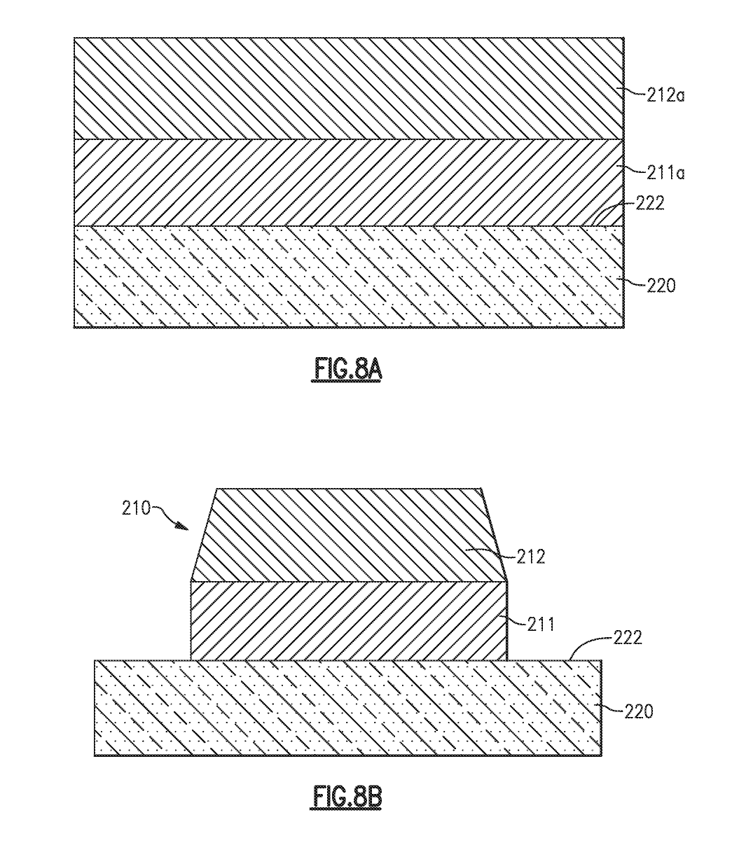

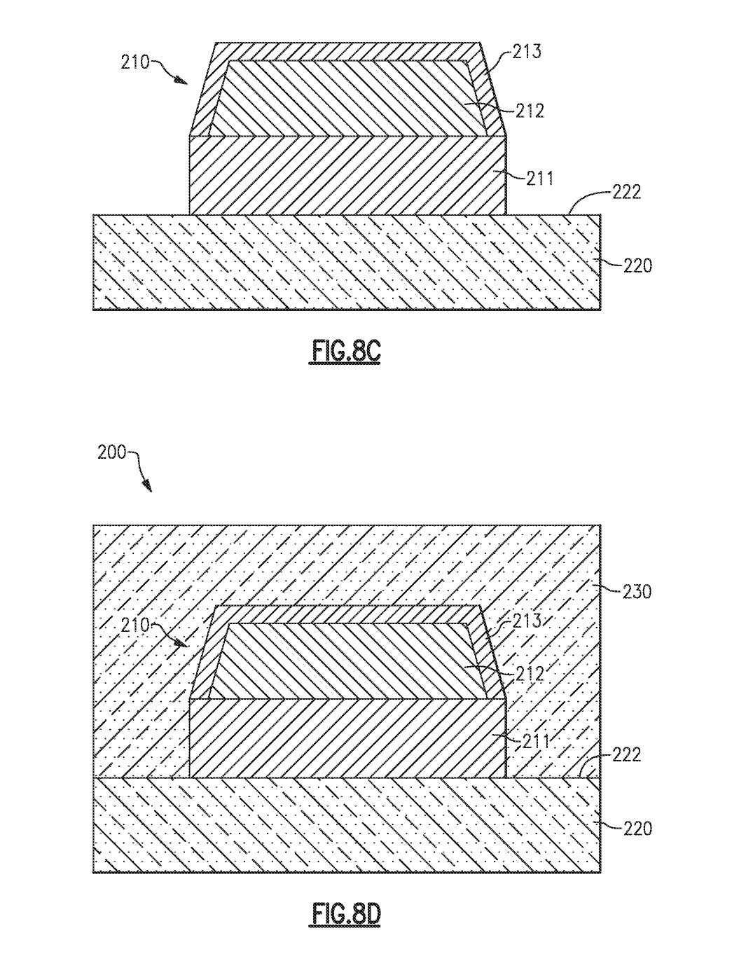

In view of the results shown in FIG. 7 and discussed above, the film thickness of the protective film 213 may advantageously range between 5 nm and 50 nm, preferably between 10 nm and 20 nm, to extend the lifetime of the SAW element according to the first embodiment. FIGS. 8A to 8D show structures corresponding to a series of method steps of manufacturing a SAW element according to the first embodiment. As shown in FIG. 8A, a first metal layer 211a is formed by depositing molybdenum on a flat top surface 222 of a piezoelectric substrate 220 made of tantalum niobate to a certain height, and then a second metal layer 212a is formed by depositing aluminum on the first metal layer 211a to a certain height.

The first metal layer 211a and the second metal layer 212a stacked on the piezoelectric substrate 220 as shown in FIG. 8A are processed by photolithography to remove certain portions such that the first metal layer 211 and the second metal layer 212 forming the electrode 210 are created as shown in FIG. 8B. As discussed above, the second metal layer 212 of aluminum is formed to have a trapezoidal cross-section.

As shown in FIG. 8C, the second metal layer 212 of aluminum is oxidized from the surface and the aluminum is converted into aluminum oxide to a certain depth, such that the protective film 213 of aluminum oxide is formed. As shown in FIG. 8D, the insulation layer 230 of silicon dioxide is formed to cover the electrode 210 including the protective film 213 formed as shown in FIG. 8C.

Thus, by way of the steps corresponding to the structures shown in FIGS. 8A to 8D, the SAW element 200 of the first embodiment is formed. The SAW element of the first embodiment can be manufactured using known techniques such as chemical vapor deposition (CVD) and sputtering.

It is to be appreciated that although the metal of the first metal layer 211 is described above as being molybdenum, it is not limited thereto. The metal of the first metal layer 211 may be any metal that can support an adequate weight and has a coefficient of thermal expansion lower than that of the second metal layer 212, a Young's modulus higher than that of the second metal layer 212, and fracture toughness higher than that of the insulation layer 230. For example, the metal may be elemental tungsten, an alloy including molybdenum, or an alloy including tungsten.

Further, although the metal of the second metal layer 212 is described above as being aluminum, it is not limited thereto. The metal of the second metal layer 212 may be any metal that can provide an adequate conductivity to the second metal layer 212. For example, the metal may be elemental copper, an alloy including aluminum, or an alloy including copper.

The material of the protective film 213 is also not limited to aluminum oxide, and may be a material that has a linear expansion coefficient lower than that of the second metal layer 212, a Young's modulus higher than that of the second metal layer 212, and fracture toughness higher than that of the insulation layer 230. For example, the material may be aluminum nitride (AlN) or may be a coating formed by depositing molybdenum, tungsten, or an appropriate alloy.

In certain examples the piezoelectric substrate 220 is a substrate made of lithium niobate, but it is not limited thereto. For example, another piezoelectric body, such as lithium tantalate (LiTaO₃), can be used for the piezoelectric substrate 220.

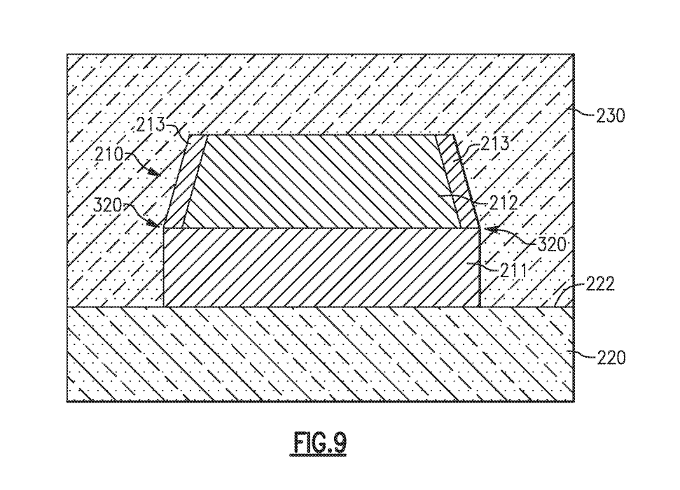

FIG. 9 is a cross-sectional view showing the structure of an electrode according to a second embodiment. The second embodiment is similar to the first embodiment, and like reference numerals indicate like elements, but is different from the first embodiment in that the top surface of the second metal layer 212 of aluminum is not covered with the protective film 213.

According to the second embodiment, a first metal layer 211 of molybdenum is formed on the top surface 222 of the piezoelectric substrate 220, and a second metal layer 212 of aluminum is formed on the first metal layer 211. In one example the piezoelectric substrate 220 is made of tantalum niobate. The second metal layer 212 of aluminum is formed to have a trapezoidal cross-section and a side surface of the second metal layer 212 is converted from aluminum into aluminum oxide to a certain depth to form a protective film 213, as discussed above. An insulation layer 230 of silicon dioxide is formed on the top surface 222 of the piezoelectric substrate 220 to cover the electrode 210.

According to the second embodiment, the protective film 213 of aluminum oxide is formed on the side surfaces of the second metal layer 212 of aluminum to cover the second metal layer 212 together with the first metal layer 211. Therefore, the second metal layer 212 of aluminum has an acute-angled region 320 covered by the molybdenum of the first metal layer 211 and the aluminum oxide of the protective film 213, each of which has a lower coefficient of thermal expansion, a higher Young's modulus, and higher fracture toughness than does aluminum. Further, the aluminum oxide of the protective film 213 has higher fracture toughness by itself. Still further, the protective film 213 of aluminum oxide only covers the side surfaces of the second metal layer 212 of aluminum. Accordingly, stresses applied within the protective film 213 may be prevented from concentrating on a region in contact with the acute-angled region 320 of the second metal layer 212 of aluminum such that cracking initiated from the protective film 213 toward the insulation layer 230 can be suppressed.

According to the second embodiment, the protective film 213 is formed only on the side surfaces of the second metal layer 212 of aluminum. Therefore, as compared to first embodiment in which the protective film 213 is formed on both of the side surfaces and the top surface of the second metal layer 212, a step of removing the protective film 213 formed on the top surface of the second metal layer 212 may be performed.

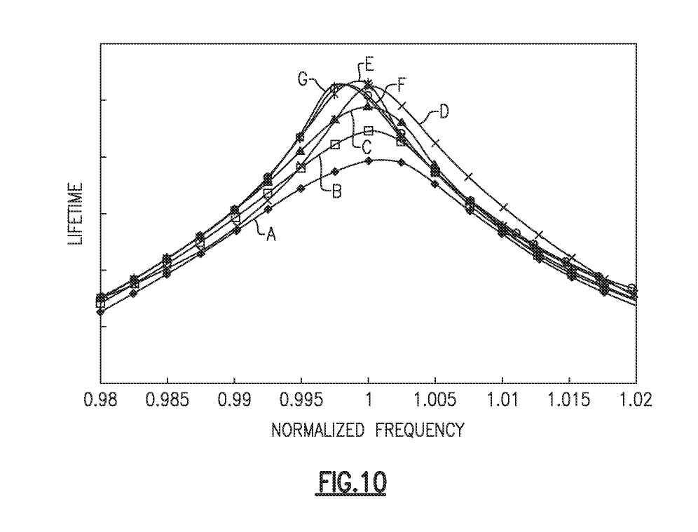

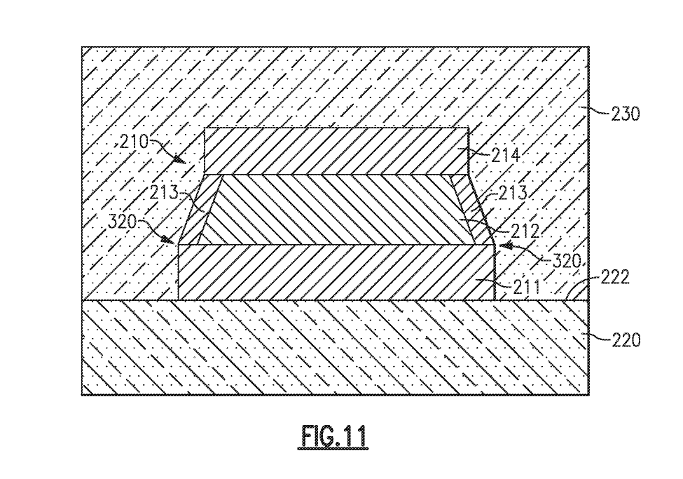

FIG. 10 is a graph showing a relationship between a lifetime of the SAW element and a film thickness of the protective film 213 according to the second embodiment. In FIG. 10, the horizontal axis represents a normalized frequency relative to the resonance frequency of the SAW element 200, and the vertical axis represents the lifetime of the SAW element in arbitrary units. In FIG. 10, similar to FIG. 7, line A (+) corresponds to an example in which no protective film is included, and lines B (□), C (▴), D (x), E (*), F (∘) and G(|) correspond to film thicknesses of 5 nm, 10 nm, 20 nm, 50 nm, 80 nm, and 100 nm respectively.

Similar to the examples shown in FIGS. 5 and 7, the lifetime of the SAW element was measured as follows: a power of 1 W was applied across the SAW element maintaining the temperature at 100° C. and then the time was measured until the insulation layer 230 of the SAW element was fractured. In the results presented in FIG. 10, each of lines B to G corresponding to the film thicknesses of 5 nm to 100 nm of the protective film 213 shows a lifetime longer than line A corresponding to the example with no protective film. Accordingly, it is demonstrated that forming the protective film 213 having a film thickness of 5 nm or greater, for example, can extend the lifetime of the SAW element of the second embodiment.

FIG. 11 is a cross-sectional view showing the structure of an electrode according to a third embodiment. The third embodiment is similar to the first embodiment, but is different therefrom in that a third metal layer 214 of molybdenum is formed on the top surface of the second metal layer 212 of aluminum, rather than the top surface of the second metal layer 212 being covered with the protective film 213.

According to the third embodiment, a first metal layer 211 of molybdenum is formed on the top surface 222 of the piezoelectric substrate 220, a second metal layer 212 of aluminum is formed on the first metal layer 211, and a third metal layer 214 of molybdenum is formed on the second metal layer 212. In one example the piezoelectric substrate 220 is made of tantalum niobate. The second metal layer 212 of aluminum is formed to have a trapezoidal cross-section and a side surface of the second metal layer 212 is converted from aluminum into aluminum oxide to a certain depth to form a protective film 213. An insulation layer 230 of silicon dioxide is formed on the top surface 222 of the piezoelectric substrate 220 to cover the electrode 210.

According to the third embodiment, the protective film 213 of aluminum oxide is formed on the side surfaces of the second metal layer 212 of aluminum, as shown in FIG. 11. Therefore, the second metal layer 212 of aluminum has an acute-angled region 320 covered by the molybdenum of the first metal layer 211 and the aluminum oxide of the protective film 213, each of which has a lower coefficient of thermal expansion, a higher Young's modulus, and higher fracture toughness than does aluminum. Further, the aluminum oxide of the protective film 213 has higher fracture toughness by itself. Still further, the protective film 213 of aluminum oxide only covering the side surfaces of the second metal layer 212 of aluminum can prevent the concentration of stresses applied within the protective film 213. Accordingly, cracking initiated from the interface between the acute-angled region 320 of the second metal layer 212 of aluminum and the protective film 213 can be suppressed.

According to the third embodiment, the first metal layer 211 and the third metal layer 214 are made of molybdenum having sufficient density to support the weight of other layers, and the second metal layer 212 is made of aluminum that provides adequate conductivity for the electrode 210. Thus, sandwiching the second metal layer 212 between the first metal layer 211 and the third metal layer 214, both of which can adequately bear weight, can vertically distribute the weight of the electrode 210 to ensure a stable oscillation of the electrode 210.

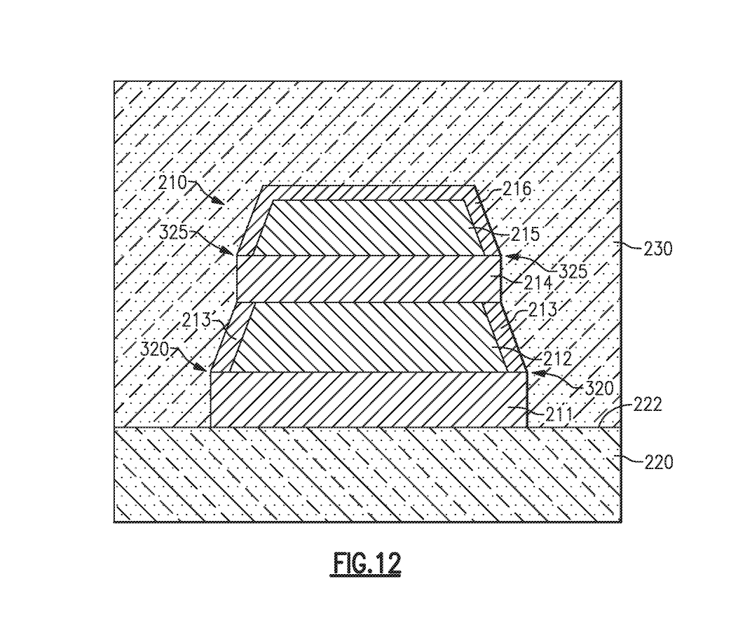

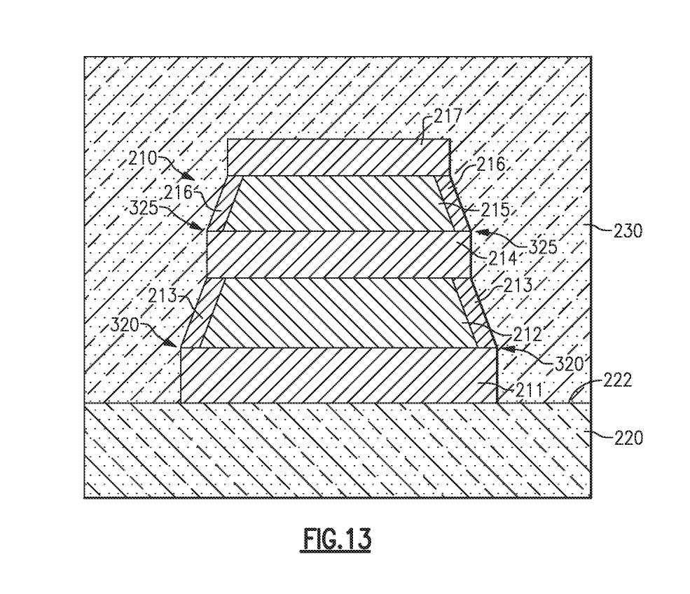

FIG. 12 is a cross-sectional view of the structure of an electrode according to a fourth embodiment. The fourth embodiment is similar to the first embodiment, but different in that the second metal layer 212 of aluminum has a top surface provided with a third metal layer 214 of molybdenum and a fourth metal layer 215 of aluminum, rather than being covered with the protective film 213.

According to the fourth embodiment, a first metal layer 211 of molybdenum is formed on the top surface 222 of the piezoelectric substrate 220, which may be made of tantalum niobate, for example. A second metal layer 212 of aluminum is formed on the first metal layer 211, and a third metal layer 214 of molybdenum is formed on the second metal layer 212. Further, a fourth metal layer 215 of aluminum is formed on the third metal layer 214 of molybdenum. Each of the second metal layer 212 and the fourth metal layer 215 of aluminum is formed to have a trapezoidal cross-section. A side surface of the second metal layer 212 and a side surface and a top surface of the fourth metal layer 215 are converted from aluminum into aluminum oxide to a certain depth to form a first protective film 213 and a second protective film 216. An insulation layer 230 of silicon dioxide is formed on the top surface 222 of the piezoelectric substrate 220 to cover the electrode 210.

According to the fourth embodiment, the first protective film 213 of aluminum oxide is formed on the side surfaces of the second metal layer 212 of aluminum to cover the second metal layer 212 together with the first metal layer 211 and the third metal layer 214. Therefore, the second metal layer 212 of aluminum has an acute-angled region 320 covered by the molybdenum of the first metal layer 211 and the aluminum oxide of the first protective film 213, each of which has a lower coefficient of thermal expansion, a higher Young's modulus, and higher fracture toughness than does aluminum. Further, the aluminum oxide of the first protective film 213 has higher fracture toughness by itself. Still further, the first protective film 213 of aluminum oxide only covering the side surfaces of the second metal layer 212 of aluminum can prevent the concentration of stresses applied within the first protective film 213. Accordingly, cracking initiated from the interface between the acute-angled region 320 of the second metal layer 212 of aluminum and the first protective film 213 can be suppressed.

Further, the second protective film 216 of aluminum oxide is formed on the side surfaces and the top surface of the fourth metal layer 215 of aluminum to cover the fourth metal layer 215 together with the third metal layer 214. Accordingly, an acute-angled region 325 of the fourth metal layer 215 of aluminum is covered by the molybdenum of the third metal layer 214 and the aluminum oxide of the second protective film 216, each of which has a lower coefficient of thermal expansion, a higher Young's modulus, and higher fracture toughness than does of aluminum. Still further, the aluminum oxide of the second protective film 216 has higher fracture toughness by itself. Yet still further, the second protective film 216 of aluminum oxide only covering the side surfaces and the top surface of the fourth metal layer 215 of aluminum can prevent the concentration of stresses applied within the second protective film 216. Accordingly, cracking initiated from the interface between the acute-angled region 325 of the fourth metal layer 215 of aluminum and the second protective film 216 can be suppressed.

In the SAW element of the fourth embodiment, the first metal layer 211 and the third metal layer 214 are made of molybdenum, which as discussed above has sufficient density to support the weight of other layers, and the second metal layer 212 and the fourth metal layer 215 are made of aluminum which provides adequate conductivity for the electrode 210. Thus, arranging the first metal layer 211 and the third metal layer 214 of molybdenum to alternate with the second metal layer 212 and the fourth metal layer 215 can vertically distribute the weight of the electrode 210 to ensure a stable oscillation of the electrode 210. Further, both electric current and generated heat are advantageously distributed between the second metal layer 212 and the fourth metal layer 215 due to the aluminum having relatively high conductivity.

FIG. 13 is a cross-sectional view showing the structure of an electrode according to a fifth embodiment. The fifth embodiment similar to the first embodiment, but is different in that instead of having the top surface of the second metal layer 212 of aluminum being covered with the protective film 213, a third metal layer 214 of molybdenum, a fourth metal layer 215 of aluminum, and a fifth metal layer 217 of molybdenum are formed over the top surface of the second metal layer 212.

According to the fifth embodiment, a first metal layer 211 of molybdenum is formed on the top surface 222 of the piezoelectric substrate 220, which may be made of tantalum niobate, for example. A second metal layer 212 of aluminum is formed on the first metal layer 211, and a third metal layer 214 of molybdenum is formed on the second metal layer 212. Further, a fourth metal layer 215 of aluminum is formed on the third metal layer 214 of molybdenum and a fifth metal layer 217 of molybdenum is formed on the fourth metal layer 215. Each of the second metal layer 212 and the fourth metal layer 215 of aluminum is formed to have a trapezoidal cross-section, and a side surface thereof is converted from aluminum into aluminum oxide to a certain depth to form a first protective film 213 and a second protective film 216. An insulation layer 230 of silicon dioxide is formed on the top surface 222 of the piezoelectric substrate 220 to cover the electrode 210.

According to the fifth embodiment, the first protective film 213 of aluminum oxide is formed on the side surfaces of the second metal layer 212 of aluminum to cover the second metal layer 212 together with the first metal layer 211 and the third metal layer 214. Therefore, the second metal layer 212 of aluminum has an acute-angled region 320 covered by the molybdenum of the first metal layer 211 and the aluminum oxide of the first protective film 213, each of which has a lower coefficient of thermal expansion, a higher Young's modulus, and higher fracture toughness than does aluminum. Further, the aluminum oxide of the first protective film 213 has higher fracture toughness by itself. Still further, the first protective film 213 of aluminum oxide only covering the side surfaces of the second metal layer 212 of aluminum can prevent the concentration of stresses applied within the first protective film 213. Accordingly, cracking initiated from the interface between the acute-angled region 320 of the second metal layer 212 of aluminum and the first protective film 213 can be suppressed.

Further, the second protective film 216 of aluminum oxide is formed on the side surfaces of the fourth metal layer 215 of aluminum to cover the fourth metal layer 215 together with the third metal layer 214 and the fifth metal layer 217. Accordingly, an acute-angled region 325 of the fourth metal layer 215 of aluminum is covered by the molybdenum of the third metal layer 214 and the aluminum oxide of the second protective film 216, each of which has a lower coefficient of thermal expansion, a higher Young's modulus, and higher fracture toughness than does of aluminum. Still further, the aluminum oxide of the second protective film 216 has higher fracture toughness by itself. Yet still further, the second protective film 216 of aluminum oxide only covering the side surfaces of the fourth metal layer 215 of aluminum can distribute the stresses. Accordingly, cracking initiated from the interface between the acute-angled region 325 of fourth metal layer 215 of aluminum and the second protective film 216 can be suppressed.

In the SAW element of fifth embodiment, the first metal layer 211, the third metal layer 214 and the fifth metal layer 217 are made of molybdenum, providing weight-bearing capability, and the second metal layer 212 and the fourth metal layer 215 are made of aluminum having higher conductivity. Thus, sandwiching the second metal layer 212 and the fourth metal layer 215 with the first metal layer 211, the third metal layer 214 and the fifth metal layer 217 of molybdenum can vertically distribute the weight of the electrode 210 to ensure a stable oscillation of the electrode 210. Further, both electric current and generated heat are advantageously distributed between the second metal layer 212 and the fourth metal layer 215 due to the conductivity of the aluminum.

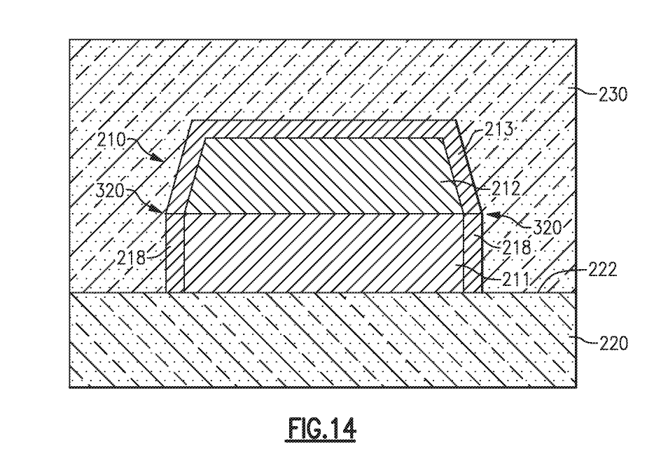

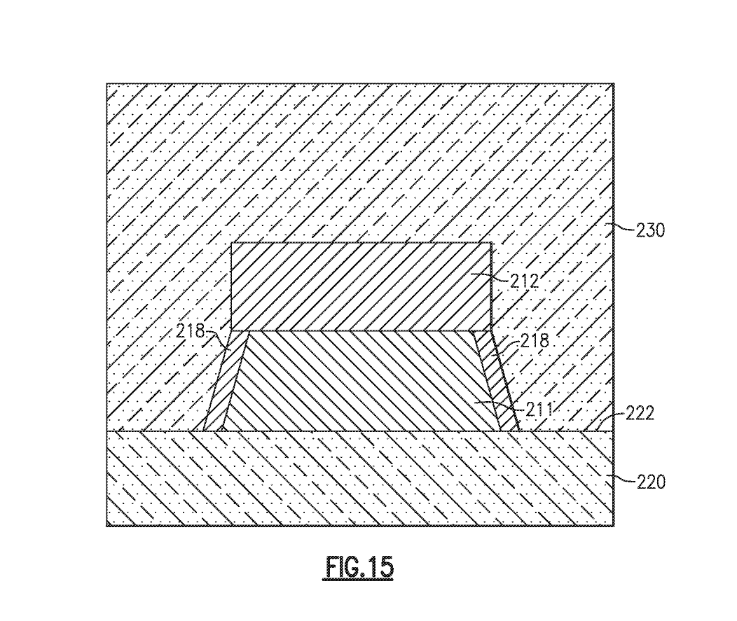

FIG. 14 is a cross-sectional view showing the structure of an electrode according to a sixth embodiment. The sixth embodiment is similar to the first embodiment, but is different therefrom in that the side surfaces of the first metal layer 211 of molybdenum are covered with a first protective film 218.

According to the sixth embodiment, a first metal layer 211 of molybdenum is formed on the top surface 222 of the piezoelectric substrate 220, which may be made of tantalum niobate, for example, and a second metal layer 212 of aluminum is formed on the first metal layer 211. A first protective film 218 is formed by converting the molybdenum of the first metal layer 211 into molybdenum oxide to a certain depth to cover the first metal layer 211 together with the top surface 222 of the piezoelectric substrate 220 and the second metal layer 212. The second metal layer 212 of aluminum is formed to have a trapezoidal cross-section and a side surface of the second metal layer 212 is converted from aluminum into aluminum oxide to a certain depth to form a second protective film 213. The second metal layer 212 of aluminum is protected by the first metal layer 211 of molybdenum between the first protective film 218 of molybdenum oxide and the second metal layer 212 of aluminum. An insulation layer 230 of silicon dioxide is formed on the top surface 222 of piezoelectric substrate 220 to cover the electrode 210.

According to the sixth embodiment, the second protective film 213 of aluminum oxide is formed on the side surfaces and the top surface of the second metal layer 212 of aluminum to cover the second metal layer 212 together with the first metal layer 211. Further, the first metal layer 211 of molybdenum is disposed between the first protective film 218 of molybdenum oxide and the second metal layer 212 of aluminum. Therefore, the second metal layer 212 of aluminum has an acute-angled region 320 covered by the molybdenum of the first metal layer 211 and the aluminum oxide of the second protective film 213, each of which has a lower coefficient of thermal expansion, a higher Young's modulus, and higher fracture toughness than does aluminum. Still further, the aluminum oxide of the second protective film 213 has higher fracture toughness by itself. Yet still further, the second protective film 213 of aluminum oxide only covering the side surfaces and the top surface of the second metal layer 212 of aluminum can prevent the concentration of stresses applied within the second protective film 213. Accordingly, cracking initiated from the interface between the acute-angled region 320 of the second metal layer 212 of aluminum and the second protective film 213 can be suppressed.

According to the sixth embodiment, the first protective film 218 of molybdenum oxide is formed on the side surfaces of the first metal layer 211 of molybdenum to protect the first metal layer 211 of molybdenum. The second metal layer 212 of aluminum is protected by the first metal layer 211 of molybdenum and the second protective film 213 of aluminum oxide.

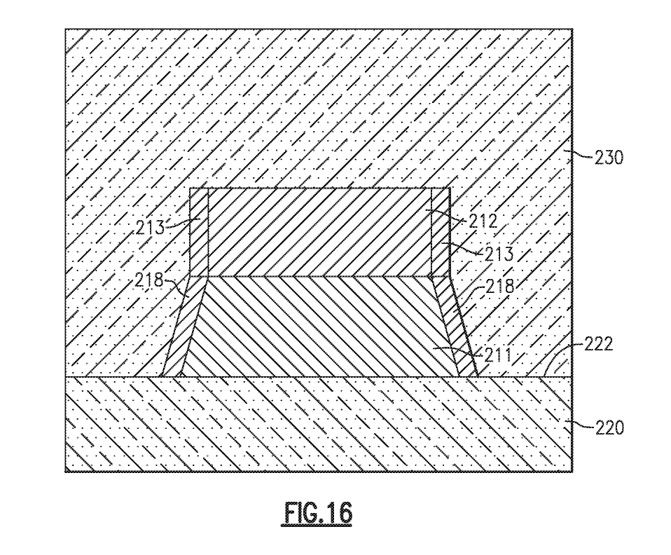

FIG. 15 is a cross-sectional view showing the structure of an electrode according to a seventh embodiment. According to the seventh embodiment, a first metal layer 211 of aluminum is formed on the top surface 222 of the piezoelectric substrate 220 and a second metal layer 212 of molybdenum is formed on the first metal layer 211. The piezoelectric substrate may be made of tantalum niobate, for example. The first metal layer 211 of aluminum is formed to have a trapezoidal cross-section and a side surface thereof is converted from aluminum into aluminum oxide to a certain depth to form a first protective film 218.

According to the seventh embodiment, the first protective film 218 of aluminum oxide is formed on the side surfaces of the first metal layer 211 of aluminum to cover the first metal layer 211 together with the top surface 222 of the piezoelectric substrate 220 and the second metal layer 212. A cross-sectional shape of the first metal layer 211 has an obtuse angle around a point where an interface between the first metal layer 211 and the second metal layer 212 is in contact with the first protective film 218. The acute-angled region 320 according to any of the first to sixth embodiments does not exist such that stresses are not concentrated within the first protective film 218.

According to the seventh embodiment again, the first metal layer 211 of aluminum is covered by the molybdenum of the second metal layer 212 and the aluminum oxide of the first protective film 218, each of which has a lower coefficient of thermal expansion, a higher Young's modulus, and higher fracture toughness than those of aluminum. Further, the aluminum oxide of the first protective film 218 has higher fracture toughness by itself. Accordingly, cracking initiated from the interface between the first metal layer 211 of aluminum and the first protective film 218 can be suppressed.

According to the seventh embodiment, the second metal layer 212 of molybdenum is formed on the top surface of the first metal layer 211 of aluminum. Therefore, the top surface of the first metal layer 211 of aluminum is protected by the second metal layer 212 of molybdenum.

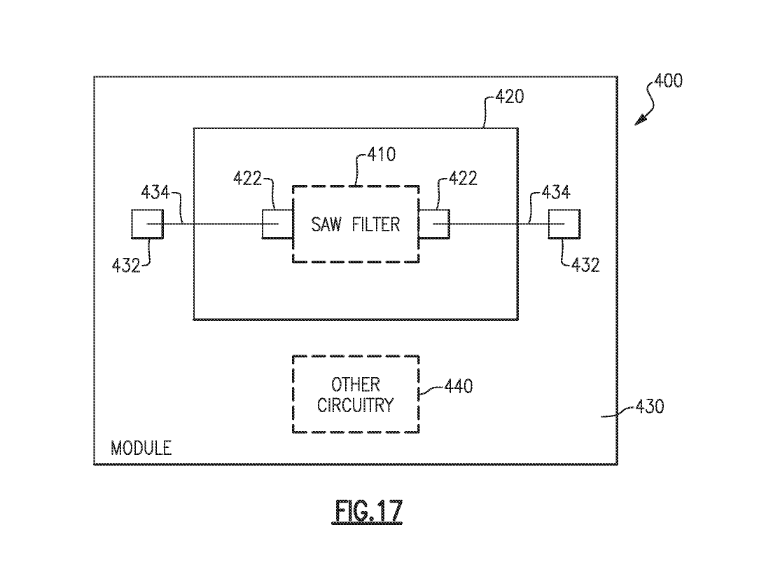

FIG. 16 is a cross-sectional view showing the structure of an electrode according to an eighth embodiment. The eighth embodiment is similar to the seventh embodiment, but is different therefrom in that a second protective film 213 of molybdenum oxide is formed on the side surfaces of the second metal layer 212 of molybdenum.

According to the eighth embodiment, a first metal layer 211 of aluminum is formed on the top surface 222 of the piezoelectric substrate 220 of tantalum niobate to cover the first metal layer 211 together with the top surface 222 of the piezoelectric substrate 220 and the second metal layer 212. A second metal layer 212 of molybdenum is formed on the first metal layer 211. The first metal layer 211 of aluminum is formed to have a trapezoidal cross-section and a side surface thereof is converted from aluminum into aluminum oxide to a certain depth to form a first protective film 218. A second protective film 213 is formed by converting the molybdenum on a side surface of the second metal layer 212 into molybdenum oxide to a certain depth to cover the second metal layer 212 together with the first metal layer 211.

According to the eighth embodiment, the second metal layer 212 of molybdenum is disposed between the second protective film 213 of molybdenum oxide and the first metal layer 211 of aluminum. The first metal layer 211 of aluminum is covered by the molybdenum of second metal layer 212 and the aluminum oxide of the first protective film 218, each of which has a lower coefficient of thermal expansion, a higher Young's modulus, and higher fracture toughness than those of aluminum. Further, the aluminum oxide of the first protective film 218 has higher fracture toughness by itself. Accordingly, cracking initiated from an interface of the first metal layer 211 of aluminum can be suppressed.

According to the eighth embodiment, the top surface of the first metal layer 211 of aluminum is protected by the second metal layer 212 of molybdenum. The molybdenum of the second metal layer 212 is disposed between the first metal layer 211 of aluminum and the second protective film 213 of molybdenum oxide and protects the first metal layer 211 of aluminum.

It is to be appreciated that although electrodes 210 have been described and illustrated as including two to five metal layers, any of the metal layers may be configured as multi-layered structures having two or more layers. In certain embodiments, when a plurality of metal layers are stacked on the top surface of the piezoelectric substrate, the odd-numbered layers counted from the lowermost layer (closest to the piezoelectric substrate 220) may be made of a metal configured to bear the weight of other layers, whereas the even-numbered layers may be made of a metal having sufficiently high conductivity for operation of the electrode 210. In other embodiments, the even-numbered layers counted from the lowermost layer may be made of a metal configured to bear the weight of other layers, whereas the odd-numbered layers may be made of a metal having sufficiently high conductivity for operation of the electrode 210. In other embodiments, the weight-bearing and high-conductivity (or conductivity-supplying) metal layers need not be strictly alternating; instead some of the metal layers in a multi-layered structure may be made of a metal configured to bear the weight of other layers, whereas other layers may be made of a metal having sufficiently high conductivity for operation of the electrode 210.

Further, layers made of the conductivity-supplying metal may have a side surface provided with a protective film, or layers made of the weight-bearing metal may have a side surface provided with a protective film. Still further, a protective film may be formed on a top surface of the uppermost layer (furthest from the piezoelectric substrate) among the plurality of metal layers.

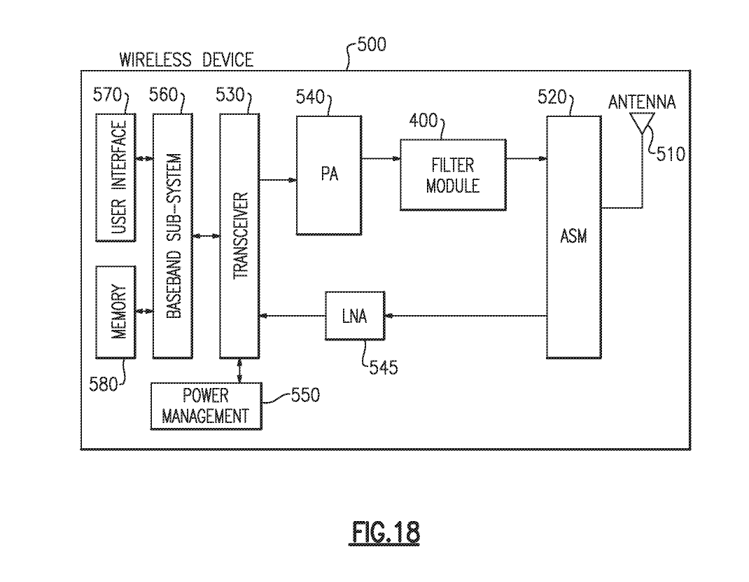

Various examples and embodiments of the SAW element 200 may be incorporated into and packaged as a module that may ultimately be used in an electronic device, such as a wireless communications device, for example. In certain examples the SAW element 200 can be configured as a SAW filter. FIG. 17 is a block diagram illustrating one example of a filter module 400 including a SAW filter 410. The SAW filter 410 may be implemented on one or more die(s) 420 including one or more connection pads 422. The packaged module 400 includes a packaging substrate 430 that is configured to receive a plurality of components, including the die 420. A plurality of connection pads 432 can be disposed on the packaging substrate 430, and the various connection pads 422 of the SAW filter die 410 can be connected to the connection pads 432 on the packaging substrate 430 via electrical connectors 434, which can be solder bumps or wirebonds, for example, to allow for passing of various signals to and from the SAW filter 410. The module 400 may optionally further include other circuitry die 440, such as, for example one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

As discussed above, various examples and embodiments of the SAW filter 410 can be used in a wide variety of electronic devices. For example, the SAW filter 410 can be used in an antenna duplexer, which itself can be incorporated into a variety of electronic devices, such as RF front-end modules and communication devices.

FIG. 18 is a block diagram of one example of a wireless device 500 including a filter module 400. The wireless device 500 can be a cellular phone, smart phone, tablet, modem, communication network or any other portable or non-portable device configured for voice or data communication. The wireless device 500 can receive and transmit signals from an antenna 510. The antenna 510 is coupled to an antenna switch module 520 that can enable switching between a transmit mode and a receive mode, for example, or between different frequency bands within the transmit mode or receive mode, for example. The wireless device 500 further includes a transceiver 530 that is configured to generate signals for transmission and/or to process received signals. Signals generated for transmission are received by a power amplifier (PA) 540, which amplifies the generated signals from the transceiver 530. Received signals are amplified by a low noise amplifier (LNA) 545 and then provided to the transceiver 530. As is also shown in FIG. 18, the antenna 510 both receives signals that are provided to the transceiver 530 via the antenna switch module 520 and the LNA 545 and also transmits signals from the wireless device 500 via the transceiver 530, the PA 540, and the antenna switch module 520. However, in other examples multiple antennas can be used.

The power amplifier 540 can be used to amplify a wide variety of RF or other frequency-band transmission signals. For example, the power amplifier 540 can receive an enable signal that can be used to pulse the output of the power amplifier to aid in transmitting a wireless local area network (WLAN) signal or any other suitable pulsed signal. The power amplifier 540 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the power amplifier 540 and associated components including switches and the like can be fabricated on GaAs substrates using, for example, pHEMT or BiFET transistors, or on a Silicon substrate using CMOS transistors.

In the example shown in FIG. 18, the filter module 400 is shown in the transmit path positioned between the power amplifier 540 and the antenna switch module 520. However, a variety of other configurations can be implemented. For example, the wireless device 500 can include one or more filter modules 400 in the transmit path or the receive path. Further, the filter module(s) 400 can be positioned before or after amplifiers or switches in either path.

The wireless device 500 of FIG. 18 further includes a power management sub-system 550 that is connected to the transceiver 530 and manages the power for the operation of the wireless device 500. The power management system 550 can also control the operation of a baseband sub-system 560 and various other components of the wireless device 500. The power management system 550 can include, or can be connected to, a battery (not shown) that supplies power for the various components of the wireless device 500.

In certain embodiments, the baseband sub-system 560 is connected to a user interface 570 to facilitate various input and output of voice and/or data provided to and received from the user.

The baseband sub-system 560 can also be connected to memory 580 that is configured to store data and/or instructions to facilitate the operation of the wireless device, and/or to provide storage of information for the user.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. It is to be appreciated that embodiments discussed herein are not limited in application to the details of construction and the arrangement of components set forth in the foregoing description. The concepts and technology disclosed herein are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment. Accordingly, the foregoing description is by way of example only, and the scope of the invention should be determined from proper construction of the appended claims, and their equivalents.

What is claimed is:

1. A surface acoustic wave device comprising:
a piezoelectric substrate;
a comb-shaped electrode formed on a top surface of the piezoelectric substrate and including a plurality of electrode fingers, each electrode finger including a first metal layer made of a first metal and formed on the top surface of the piezoelectric substrate, a second metal layer made of a second metal and formed on the first metal layer, and a first protective film at least partially covering the second metal layer; and
an insulation layer formed over the top surface of the comb-shaped electrode to cover the piezoelectric substrate.

2. The surface acoustic wave device of claim 1 wherein the first metal has a first conductivity and the second metal has a second conductivity greater than the first conductivity.

3. The surface acoustic wave device of claim 1 wherein the first metal has a first density and the second metal has a second density less than the first density.

4. The surface acoustic wave device of claim 1 wherein the second metal layer has a trapezoidal cross-section taken along a line perpendicular to an extending direction of the electrode finger.

5. The surface acoustic wave device of claim 4 wherein the first protective film covers side surfaces and a top surface of the second metal layer.

6. The surface acoustic wave device of claim 4 wherein the first protective film covers side surfaces of the second metal layer and does not extend over a top surface of the second metal layer.

7. The surface acoustic wave device of claim 1 wherein the insulation layer is made of a first material having a first fracture toughness value, and the first protective film is made of a second material having a second fracture toughness value greater than the first fracture toughness value.

8. The surface acoustic wave device of claim 7 wherein the second material of the first protective film is oxidized from the second metal.

9. The surface acoustic wave device of claim 8 wherein the second material of the first protective film is nitrided from the second metal.

10. The surface acoustic wave device of claim 1 wherein the first metal layer is made of molybdenum and the second metal layer is made of aluminum.

11. The surface acoustic wave device of claim 10 wherein the first protective film is made of aluminum oxide.

12. The surface acoustic wave device of claim 1 wherein each electrode finger further includes a third metal layer made of the first metal and disposed on a top surface of the second metal layer.

13. The surface acoustic wave device of claim 12 wherein the second metal layer is covered by the first protective film, the first metal layer, and the third metal layer.

14. The surface acoustic wave device of claim 12 wherein each electrode finger further includes a fourth metal layer made of the second metal and disposed on a top surface of the third metal layer.

15. The surface acoustic wave device of claim 14 wherein the fourth metal layer has a trapezoidal cross-section taken along a line perpendicular to an extending direction of the electrode finger.

16. The surface acoustic wave device of claim 15 wherein each electrode finger further includes a second protective film covering side surfaces and a top surface of the fourth metal layer.

17. The surface acoustic wave device of claim 1 wherein each electrode finger further includes a second protective film at least partially covering the first metal layer, the first metal being covered by the second protective film and the top surface of the piezoelectric substrate.

18. The surface acoustic wave device of claim 17 wherein the second protective film includes material oxidized from the first metal.

19. A method of manufacturing a surface acoustic wave device, comprising:
forming a comb-shaped electrode on a top surface of a piezoelectric substrate, including forming a first metal layer made of first metal on the top surface of the piezoelectric substrate, forming a second metal layer made of second metal on the first metal layer, and oxidizing a surface of the second metal layer to form a protective film on the second metal layer, the second metal layer being covered by the protective film and the first metal layer; and
forming an insulation layer on the top surface of the piezoelectric substrate to cover the comb-shaped electrode.

20. The method of claim 19 wherein forming the second metal layer includes forming the second metal layer to have a trapezoidal cross-section taken along a line perpendicular to an extending direction of an electrode finger of the comb-shaped electrode.
